(19) United States
(12) Patent Application Publication
(10) Pub. No.: US 2025/0176170 A1
(43) Pub. Date: May 29, 2025

(54) SEMICONDUCTOR MEMORY DEVICE

(71) Applicant: Samsung Electronics Co., Ltd., Suwon-si (KR)

(72) Inventors: JI HYE LEE, Suwon-si (KR); YANG DOO KIM, Suwon-si (KR); SANG WUK PARK, Suwon-si (KR); MIN KYU SUH, Suwon-si (KR); GEON YEOP LEE, Suwon-si (KR); DO KEUN LEE, Suwon-si (KR); JE-WOO HAN, Suwon-si (KR); JUNG PYO HONG, Suwon-si (KR)

(21) Appl. No.: 18/795,643

(22) Filed: Aug. 6, 2024

(30) Foreign Application Priority Data
Nov. 29, 2023 (KR) 10-2023-0169366

(51) Int. Cl. H10B 12/00; H01L 29/423

(52) U.S. Cl. CPC H10B 12/482; H10B 12/315; H10B 12/485; H10B 12/488; H10D 64/512

(57) ABSTRACT

A semiconductor memory device is provided. The semiconductor memory device includes: a substrate including active regions; bitline structures extending in a direction on the active regions; landing pads electrically connected to the active regions, on the bitline structures; interlayer insulating films between the landing pads, on the bitline structures; capacitor structures including lower electrodes that are on the landing pads, dielectric films that extend along the lower electrodes, and an upper electrode that is on the dielectric films; and etch stop films between the interlayer insulating films and the capacitor structures, wherein the upper electrode includes a first portion that is on the etch stop films, and a second portion that is on the first portion, and a width of the second portion is less than a width of the first portion.

### RELATED APPLICATIONS

This application claims priority from Korean Patent Application No. 10-2023-0169366 filed on Nov. 29, 2023 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates to a semiconductor memory device, and more particularly, to a semiconductor memory device including a plurality of wiring lines and contacts that intersect one another.

Due to the rapid development of the electronics industry and the diversifying demands from users, electronic devices are becoming increasingly smaller and lighter. Therefore, a higher integration is required for semiconductor memory devices used in the electronic devices, leading to a reduction in the design rules for the components of semiconductor memory devices. Consequently, the complexity of the processes for connecting the components included in the semiconductor memory devices is increasing.

### SUMMARY OF THE INVENTION

Aspects of the present disclosure provide a semiconductor memory device that reduces the complexity of its manufacturing process and ensures the connection reliability of its components during the manufacture.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor memory device includes: a substrate including active regions; bitline structures extending in a direction on the active regions; landing pads electrically connected to the active regions, on the bitline structures; interlayer insulating films between the landing pads, on the bitline structures; capacitor structures including lower electrodes that are on the landing pads, dielectric films that extend along the lower electrodes, and an upper electrode that is on the dielectric films; and etch stop films between the interlayer insulating films and the capacitor structures, wherein the upper electrode includes a first portion that is on the etch stop films, and a second portion that is on the first portion, and a width of the second portion is less than a width of the first portion.

According to another aspect of the present disclosure, a semiconductor memory device includes: a substrate including active regions that are defined by device isolation films; wordline structures extending in a first direction on the active regions; bitline structures extending in a second direction that intersects the first direction, on the wordline structures; buried contacts electrically connected to the active regions, between the bitline structures; landing pads electrically connected to the active regions, on the bitline structures; interlayer insulating films between the landing pads, on the bitline structures; capacitor structures including lower electrodes that are on the landing pads, dielectric films that extend along the lower electrodes, and an upper electrode that is on the dielectric films; and etch stop films between the interlayer insulating films and the capacitor structures, wherein the lower electrodes include first lower electrodes that contact the landing pads, third lower electrodes that are on the first lower electrodes, and second lower electrodes that are between the first lower electrodes and the third lower electrodes, and the first lower electrodes, the second lower electrodes, and the third lower electrodes form an “I” shape together.

According to another aspect of the present disclosure, a semiconductor memory device includes: a substrate including active regions that are defined by device isolation films; wordline structures extending in a first direction on the active regions; bitline structures extending in a second direction that intersects the first direction, on the wordline structures; buried contacts electrically connected to the active regions, between the bitline structures; landing pads electrically connected to the active regions, on the bitline structures; interlayer insulating films between the landing pads, on the bitline structures; lower electrode structures including first lower electrodes that contact the landing pads, third lower electrodes that are on the first lower electrodes, and second lower electrodes that are between the first lower electrodes and the third lower electrodes; etch stop films on the interlayer insulating films; and an upper electrode structure including a first portion that is on the etch stop films, and a second portion that is on the first portion, wherein a width of the second lower electrodes is less than a width of the first lower electrodes, and a width of the second portion of the upper electrode structure is less than a width of the first portion of the upper electrode structure.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout view of a semiconductor memory device according to some embodiments of the present disclosure;

FIG. 2 is a cross-sectional view taken along line A-A of FIG. 1;

FIG. 3 is a cross-sectional view taken along line B-B of FIG. 1;

FIG. 4 is an enlarged cross-sectional view of region R of FIG. 2;

FIGS. 5 and 6 are cross-sectional views of a semiconductor memory device according to some embodiments of the present disclosure;

FIGS. 7 through 26 are cross-sectional views illustrating a method of fabricating a semiconductor memory device according to some embodiments of the present disclosure;

FIG. 27 is a layout view of a semiconductor memory device according to some embodiments of the present disclosure;

FIG. 28 is a perspective view of a semiconductor memory device according to some embodiments of the present disclosure;

FIG. 29 is a cross-sectional view taken along lines D-D and E-E of FIG. 27;

FIG. 30 is a layout view of a semiconductor memory device according to some embodiments of the present disclosure; and

FIG. 31 is a perspective view of a semiconductor memory device according to some embodiments of the present disclosure.

### DETAILED DESCRIPTION

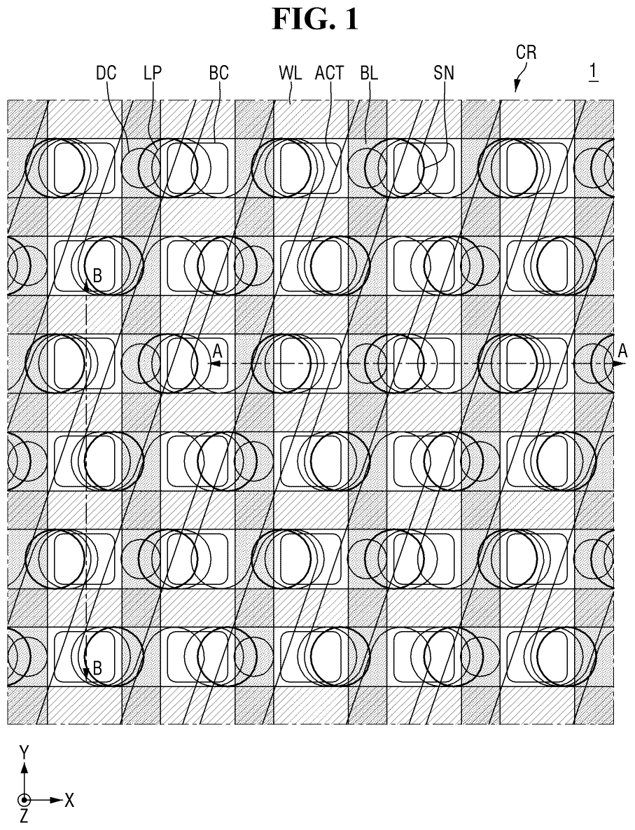

Embodiments of the present disclosure will hereinafter be described in detail with reference to the accompanying drawings. Specifically, a semiconductor memory device according to some embodiments of the present disclosure will hereinafter be described with reference to FIGS. 1 through 8.

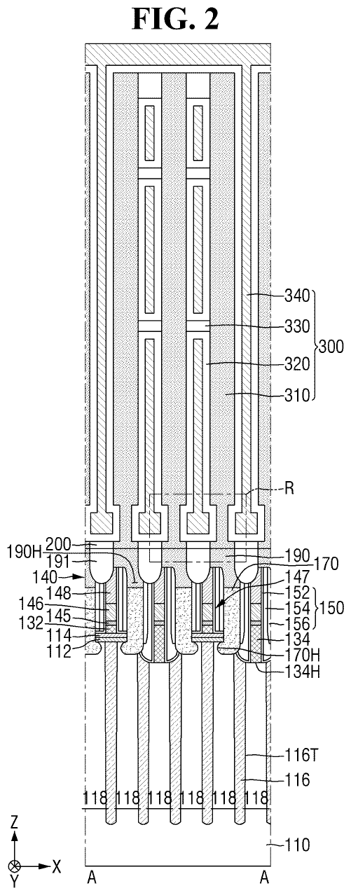

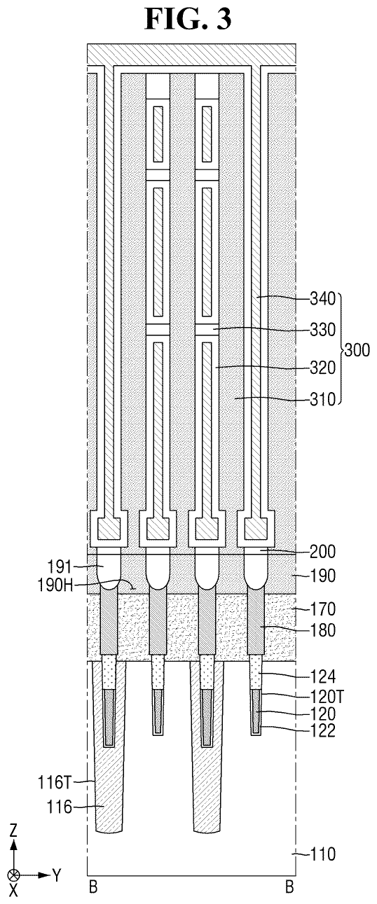

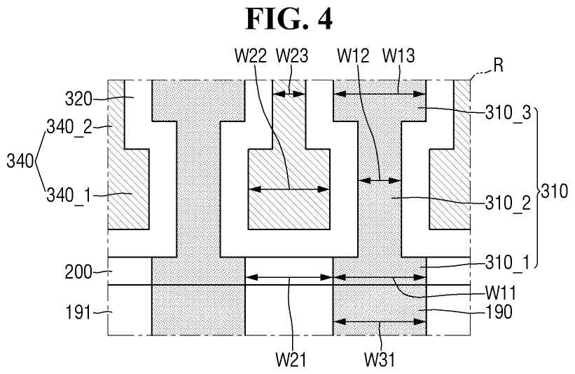

FIG. 1 is a layout view of a semiconductor memory device according to some embodiments of the present disclosure. FIG. 2 is a cross-sectional view taken along line A-A of FIG. 1. FIG. 3 is a cross-sectional view taken along line B-B of FIG. 1. FIG. 4 is an enlarged cross-sectional view of region R of FIG. 2.

Referring to FIG. 1, a semiconductor memory device 1 may include a plurality of active regions ACT. In some embodiments, the active regions ACT may be arranged with their long axes aligned in diagonal directions with respect to first and second directions X and Y, which cross each other perpendicularly.

A plurality of wordlines WL may extend in parallel along the first direction X across the active regions ACT. A plurality of bitlines BL may extend in parallel along the second direction Y, which intersects the first direction X, over the plurality of wordlines WL.

A plurality of bitlines BL can be electrically connected to the plurality of active regions ACT through direct contacts DC.

In some embodiments, buried contacts BC may be formed between pairs of adjacent bitlines BL, and may be electrically connected to the active regions ACT. In some embodiments, the buried contacts BC may be arranged in rows along each of the first and second directions X and Y.

Landing pads LP may be formed on the buried contacts BC. The landing pads LP may be disposed to at least partially overlap with the buried contacts BC. In some embodiments, each of the landing pads LP may extend to the top of one of its neighboring pair of bitlines BL. The landing pads LP may have a hexagonal array structure in a plan view. For example, in a plan view, the landing pads LP may be arranged in rows along the first direction X and in a zigzag pattern along the second direction Y forming a honeycomb shape.

Storage nodes SN may be formed on the landing pads LP. The storage nodes SN may be formed above the bitlines BL. The storage nodes SN may be the lower electrodes of capacitors. The storage nodes SN may be electrically connected to the active regions ACT through the landing pads LP and the buried contacts BC. The storage nodes SN may have a hexagonal array structure in a plan view. For example, in a plan view, the storage nodes SN may be arranged in rows along the first direction X and in zigzags along the second direction Y, thereby forming a honeycomb shape.

Referring to FIGS. 1 to 4, a semiconductor memory device according to some embodiments of the present disclosure may include a substrate 110, wordlines WL, bitlines BL, buried contacts 170, landing pads 190, interlayer insulating (e.g., dielectric) films 191, etch stop films 200, and capacitor structures 300.

The substrate 110 may include, for example, silicon (Si) such as crystalline Si, polycrystalline Si, or amorphous Si. Alternatively, the substrate 110 may include at least one compound semiconductor selected from among a semiconductor element such as germanium (Ge), silicon-germanium (SiGe), silicon carbide (SiC), gallium arsenide (GaAs), indium arsenide (InAs), and indium phosphide (InP). Alternatively, the substrate 110 may have a silicon-on-insulator (SOI) structure. For example, the substrate 110 may include a buried oxide (BOX) layer. The substrate 110 may include conductive regions or structures such as, for example, impurity-doped wells or structures.

Device isolation films 116 may include, for example, at least one of a silicon oxide film, a silicon nitride film, and a silicon oxynitride film. The device isolation films 116 may be configured as single layers consisting of one type of insulating film, double layers consisting of two types of insulating films, or multilayers consisting of at least three types of insulating films. For example, the device isolation films 116 may be configured as double layers or multilayers consisting of oxide and nitride films, but the present disclosure is not limited thereto.

A plurality of wordline trenches 120T may be formed in the substrate 110. The wordline trenches 120T may extend in parallel along the first direction X. The wordline trenches 120T may cross the active regions 118, may have a linear shape, and may be arranged at generally equal intervals along the second direction Y.

In some embodiments, the wordline trenches 120T may be formed by etching the device isolation films 116 and the substrate 110 using different etching processes, so that the etch depths of the device isolation films 116 and the substrate 110 differ. For example, the wordline trenches 120T may be formed by etching both the device isolation films 116 and the substrate 110 together, but as the device isolation films 116 and the substrate 110 have different etch rates, the etch depths of the device isolation films 116 and the substrate 110 may differ from each other.

The wordline structures WL may include gate dielectric films 122, gate electrodes 120, and buried insulating films 124, which are sequentially disposed within a wordline trench 120T.

The gate electrodes 120 may fill the lower parts of wordline trenches 120T. The buried insulating films 124 may fill the upper parts of the wordline trenches 120T, covering the gate electrodes 120. The gate electrodes 120 may extend in parallel in the first direction X and may have a linear shape, and may be arranged at generally equal intervals along the second direction Y, extending across the active regions 118. Similarly, the buried insulating layers 124 may extend in parallel in the first direction X, may have a linear shape, and may be arranged at generally equal intervals along the second direction Y, extending across the active regions 118.

For example, the gate electrodes 120 may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. In some embodiments, the gate electrodes 120 may include core layers and barrier layers disposed between the core layers and the gate dielectric films 122. For example, the core layers may include a metal material or a conductive metal nitride such as W, WN, TiSiN, or WSiN, and the barrier layers may include a metal material or conductive metal nitride such as Ti, TiN, Ta, or TaN.

The gate dielectric films 122 may be formed of at least one selected from among a silicon oxide film, a silicon nitride film, a silicon oxynitride film, an oxide/nitride/oxide (ONO) film, or a high-k dielectric film with a dielectric constant greater than that of silicon oxide. For example, the gate dielectric films 122 may have a dielectric constant of about 10 to 25.

In some embodiments, the gate dielectric films 122 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric films 122 may include HfO₂, Al₂O₃, HfAlO₃, Ta₂O₃, or TiO₂.

The top surfaces of the buried insulating films 124 may be at substantially the same level as the top surface of the substrate 110. The buried insulating films 124 may include one selected from among a silicon oxide film, a silicon nitride film, a silicon oxynitride film, and a combination thereof.

The top surfaces of the gate electrodes 120 may be positioned at a lower level than the top surface of the substrate 110. The bottom surfaces of the gate electrodes 120 may have a rugged shape, and saddle fin-shaped field-effect transistors (FinFETs) may be formed in the active regions 118.

The term “level,” as used herein, refers to the height in a third direction Z, which is perpendicular to the first and second directions X and Y, relative to the main surface of the substrate 110. That is, when elements are at the same level or at a certain level, it means that the elements have the same height in the third direction Z or are at a certain position, relative to the main surface of the substrate 110, and when one element is at a lower or higher level than another element, it means that the former element is at a lower or higher position than the latter element, relative to the main surface of the substrate 110.

In some embodiments, after the formation of the gate electrodes 120, impurity ions may be injected into portions the active regions 118 of the substrate 110 on both (i.e., opposite) sides of the gate electrodes 120 to form source/drain regions within the active regions 118. Alternatively, the injection of impurity ions for forming the source/drain regions may be performed before the formation of the gate electrodes 120.

Insulating film patterns (112 and 114) may be disposed on the device isolation films 116 and the active regions 118. For example, the insulating film patterns (112 and 114) may include a silicon oxide film, a silicon nitride film, a silicon oxynitride film, a metal-based dielectric film, or a combination thereof.

In some embodiments, the insulating film patterns (112 and 114) may be formed by stacking a plurality of insulating films, including first insulating film patterns 112 and second insulating film patterns 114. For example, the second insulating film patterns 114 may have a greater dielectric constant than the first insulating film patterns 112.

In another example, the first insulating film patterns 112 may include a non-metal-based dielectric film, and the second insulating film patterns 114 may include a metal-based dielectric film. For example, the first insulating film patterns 112 may include a silicon oxide film, a silicon nitride film, a silicon oxynitride film, or a combination thereof. Moreover, the second insulating film patterns 114 may include, for example, at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO).

Direct contact holes 134H may penetrate the insulating film patterns (112 and 114). The direct contact holes 134H may be formed to expose the source regions within the active regions 118. In some embodiments, the direct contact holes 134H may extend into, for example, the source regions within the active regions 118.

A direct contact conductive layer (not illustrated) may fill the direct contact holes 134H and cover the insulating film patterns (112 and 114). The direct contact conductive layer may include, for example, Si, Ge, tungsten (W), tungsten nitride (WN), cobalt (Co), nickel (Ni), aluminum (Al), molybdenum (Mo), ruthenium (Ru), titanium (Ti), titanium nitride (TiN), tantalum (Ta), tantalum nitride (TaN), copper (Cu), or a combination thereof. In some embodiments, the direct contact conductive layer may include an epitaxial Si layer. In some embodiments, the direct contact conductive layer may include doped polysilicon.

Bitline structures 140 may be disposed on the insulating film patterns (112 and 114) and the direct contact conductive layer. Each of the bitline structures 140 may include a metal-based conductive layer and an insulating capping layer, which are sequentially formed.

In some embodiments, the metal-based conductive layer may have a structure where first and second metal-based conductive layers are stacked. The metal-based conductive layer may have a dual-layer stack of two conductive layers, but the present disclosure is not limited thereto. Alternatively, the metal-based conductive layer may be formed as a single layer or a multilayer stack of three or more layers.

In some embodiments, the first metal-based conductive layer may include TiN or Ti—Si—N (TSN), and the second metal-based conductive layer may include W or tungsten silicide (WSiₓ). In some embodiments, the first metal-based conductive layer may function as a diffusion barrier. In some embodiments, the insulating capping layer may include a silicon nitride film.

By etching the first metal-based conductive layer, the second metal conductive layer, and the insulating capping layer, bitlines 147, which include first metal conductive patterns 145 and second metal conductive patterns 146 that are both line-shaped, and insulating capping lines 148 may be formed. One bitline 147 and one insulating capping line 148 covering the bitline 147 may form one bitline structure 140.

In some embodiments, the bitline structures 140 may further include conductive semiconductor patterns 132, which are disposed between the insulating film patterns (112 and 114) and the first metal-based conductive patterns 145. The conductive semiconductor patterns 132 may include doped polysilicon. In some embodiments, the conductive semiconductor patterns 132 may not be formed and may be omitted.

The bitline structures 140, including the bitlines 147 and the insulating capping lines 148, may extend in the second direction Y. The bitlines 147 may correspond to the bitlines BL of FIG. 1.

In an etching process for forming the bitlines 147, portions of the direct contact conductive layer that do not overlap with the bitlines 147 in the third direction Z may be removed, thereby forming a plurality of direct contact conductive patterns 134. During the etching process for forming the bitlines 147 and the direct contact conductive patterns 134, the insulating film patterns (112 and 114) may function as etch stop films. The direct contact conductive patterns 134 may form the direct contacts DC of FIG. 1. The bitlines 147 may be electrically connected to the active regions 118 through the direct contact conductive patterns 134.

During the formation of the direct contact conductive patterns 134 through the removal of portions of the direct contact conductive layer, the conductive semiconductor patterns 132 may also be formed. For example, the conductive semiconductor patterns 132 may be portions of the direct contact conductive layer that overlap with the bitlines 147 in the third direction Z, but do not overlap with the direct contact holes 134H in the third direction Z and are thus positioned on the insulating film patterns (112 and 114), or may be portions of the direct contact conductive layer that overlap with the direct contact holes 134H in the third direction Z and are thus in contact with the active regions 118.

Insulating spacer structures 150 may cover both (i.e., opposite) sidewalls of the bitline structures 140. The insulating spacer structures 150 may include first insulating spacers 152, second insulating spacers 154, and third insulating spacers 156.

The second insulating spacers 154 may be formed of a material with a smaller dielectric constant than the first insulating spacers 152 and the third insulating spacers 156. In some embodiments, the first insulating spacers 152 and the third insulating spacers 156 may include a nitride film, and the second insulating spacer 154 may include an oxide film. In some embodiments, the first insulating spacers 152 and the third insulating spacers 156 may include a nitride film, and the second insulating spacer 154 may include a material with an etch selectivity with respect to the first insulating spacers 152 and the third insulating spacers 156. For example, if the first insulating spacers 152 and the second insulating spacers 156 are formed of a nitride film, the second insulating spacers 154 may be formed of an oxide film but may be removed later in a subsequent process to become air spacers.

Buried contact holes 170H may be formed between the bitlines 147. The buried contact holes 170H may be defined by the insulating spacer structures 150 covering the sidewalls of the pairs of adjacent bitlines 147 and the active regions 118.

A plurality of buried contact holes 170H may be formed by removing portions of the insulating film patterns (112 and 114) and portions of the active regions 118 using the insulating capping lines 148 and the insulating spacer structures 150, which cover both (i.e., opposite) sidewalls of the bitline structures 140, as an etch mask.

The buried contact holes 170H may be formed by performing an anisotropic etching process first using the insulating capping lines 148 and the insulating spacer structures 150, which cover both (i.e., opposite) sidewalls of the bitline structures 147, as an etch mask to remove portions of the insulating film patterns (112 and 114) and portions of the active regions 118, and then performing an isotropic etching process to further remove other portions of the active regions 118 and thereby expand the spaces defined by the active regions 118.

The buried contacts 170 and insulating fences 180 may be disposed between the insulating spacer structures 150, which cover both (i.e., opposite) sidewalls of the bitline structures 140. The buried contacts 170 and the insulating fences 180 may be alternately arranged along the gap between each pair of opposing insulating spacer structures 150, i.e., along the second direction Y.

For example, the buried contacts 170 may include polysilicon. Moreover, the insulating fences 180 may include, for example, a nitride film.

In some embodiments, the buried contacts 170 may be arranged in rows along each of the first and second directions X and Y. The buried contacts 170 may extend in the third direction Z, perpendicular from the active regions 118 to the substrate 110. The buried contacts 170 may correspond to the buried contacts BC of FIG. 1.

The buried contacts 170 may be formed by first forming a pre-buried contact material layer filling the buried contact holes 170H, and then removing upper portions of the pre-buried contact material layer. For example, the pre-buried contact material layer may be formed of polysilicon.

The top surfaces of the buried contacts 170 may be positioned lower than the top surfaces of the insulating capping lines 148. The top surfaces of the insulating fences 180 and the top surfaces of the insulating capping lines 148 may be positioned at the same level in the third direction Z. Therefore, the top surfaces of the buried contacts 170 may be positioned lower than the top surfaces of the insulating fences 180.

In some embodiments, the insulating fences 180 may be formed first, and then, the pre-buried contact material layer may be formed. Alternatively, the pre-buried contact material layer may be formed first, and then, the insulating fences 180 may be formed. Yet alternatively, the insulating fences 180 may be formed first, then, the buried contact holes 170H may be formed, and then, the pre-buried contact material layer filling the buried contact holes 170H may be formed.

The buried contacts 170 may fill the lower portions of the gaps between the insulating spacer structures 150, which cover both (i.e., opposite) sidewalls of the bitline structures 140. In some embodiments, the buried contacts 170 may be formed such that their top surfaces are not lower than the top surfaces of the bitlines 147, but the present disclosure is not limited thereto.

The landing pads 190 may fill the landing pad holes 190H and cover the bitline structures 140.

The landing pads 190 may fill at least portions of the landing pad holes 190H and extend onto the bitline structures 140. The landing pads 190 are disposed on the buried contacts 170 and may extend onto the bitline structures 140. The landing pads 190 are disposed on the buried contacts 170 to be electrically connected to the buried contacts 170. The landing pads 190 may be electrically connected to the active regions 118 through the buried contacts 170. The landing pads 190 may correspond to the landing pads LP of FIG. 1.

The buried contacts 170 and the landing pads 190, positioned on the buried contacts 170, may be collectively referred to as contact structures. Each of the buried contacts 170 forming the contact structures may be disposed between a corresponding pair of adjacent bitline structures 140, and each of the landing pads 190 may extend from between the corresponding pair of adjacent bitline structures 140 with one of the buried contacts 170 interposed therebetween, over one of the corresponding pair of adjacent bitline structures 140.

In other words, each of the landing pads 190 may be electrically connected to the buried contacts 170 and may be formed to extend from between the corresponding pair of adjacent bitline structures 140 with one of the buried contacts 170 interposed therebetween, over and overlapping, in the third direction Z, with the top surface of one of the corresponding pair of adjacent bitline structures 140.

The landing pads 190 may include a conductive barrier layer and a conductive pad material layer on top of the conductive barrier layer. For example, the conductive barrier layer may be formed of a metal, a conductive metal nitride, or a combination thereof. In some embodiments, the conductive barrier layer may consist of a Ti/TiN stack structure. Moreover, the conductive pad material layer may be formed of, for example, a metal. In some embodiments, the conductive pad material layer may include W.

The material of the landing pads 190 will be described later in further detail with reference to FIG. 4.

The interlayer dielectric films 191 may be disposed on the bitline structures 140, between the landing pads 190. The interlayer dielectric films 191 may define the landing pads 190, which form a plurality of isolation regions. The interlayer dielectric films 191 may not cover the top surfaces of the landing pads 190. For example, the height of the top surfaces of the landing pads 190 may be the same as (i.e., coplanar with) the height of the top surface of the interlayer dielectric films 191, based on the top surface of the substrate 110.

The interlayer dielectric films 191 may include an insulating material and may electrically isolate the landing pads 190 from one another. For example, the interlayer dielectric films 191 may include at least one of a silicon oxide film, a silicon nitride film, a silicon oxynitride film, a silicon oxycarbonitride film, and a silicon carbonitride film.

The etch stop films 200 may be disposed between the interlayer dielectric films 191 and the capacitor structures 300, in the third direction Z. The etch stop films 200 may be disposed above the interlayer dielectric films 191 and below the capacitor structures 300.

The etch stop films 200 may include a nitride-based insulating material. For example, the etch stop films 200 may include at least one of silicon nitride, silicon carbonitride, silicon oxycarbonitride, and silicon boron nitride (SiBN). In some embodiments, the etch stop films 200 may have an etch selectivity relative to the interlayer dielectric films 191.

The capacitor structures 300 may be disposed on the landing pads 190. The capacitor structures 300 may include the lower electrodes 310, capacitor dielectric films 320, electrode support layers 330, and an upper electrode 340.

The lower electrodes 310 may be disposed on the substrate 110. The lower electrodes 310 may be disposed on the landing pads 190. The lower electrodes 310 may be electrically connected to the landing pads 190.

For example, the lower electrodes 310 may have a pillar shape. The lower electrodes 310 may extend longitudinally in the thickness direction of the substrate 110, i.e., in the third direction Z. The length by which the lower electrodes 310 extend in the third direction Z may be greater than the length by the lower electrodes 310 extend in the first and second directions X and Y, parallel to the main surface of the substrate 110.

For example, the lower electrodes 310 may be repetitively aligned along the first and second directions X and Y. The lower electrodes 310 may also be repetitively aligned in the second direction Y. The lower electrodes 310 may not be aligned in straight lines along the second direction Y. The lower electrodes 310 may be arranged in zigzags along the second direction Y. The lower electrodes 310 may be arranged in straight lines along the third direction Z.

The lower electrodes 310 may include a material such as a doped semiconductor material, a conductive metal nitride (e.g., titanium nitride, tantalum nitride, niobium nitride, or tungsten nitride), a metal (e.g., ruthenium, iridium, titanium, or tantalum), or a conductive metal oxide (e.g., iridium oxide or niobium oxide), but the present disclosure is not limited thereto. In some embodiments, the lower electrodes 310 may include titanium nitride (TiN). Additionally, in some embodiments, the lower electrodes 310 may include niobium nitride (NbN).

The material of the lower electrodes 310 will be described later in further detail with reference to FIG. 4.

The capacitor dielectric films 320, the electrode support layers 330, and the upper electrode 340 may be disposed between the lower electrodes 310. The electrode support layers 330 physically/structurally support the lower electrodes 310.

In the third direction Z, each of the electrode support layers 330 may be formed as multiple support layers disposed between portions (e.g., upper and lower portions) of the upper electrode 340. In some embodiments, the number of support layers included in each of the electrode support layers 330 may be three, but the present disclosure is not limited thereto.

The electrode support layers 330 may include an insulating material. For example, the electrode support layers 330 may include at least one of silicon nitride, silicon carbonitride, silicon boron nitride, silicon oxycarbide, silicon oxynitride, silicon oxide, and silicon oxycarbonitride.

The capacitor dielectric films 320 may be formed on the lower electrodes 310, the etch stop films 200, the landing pads 190, and the electrode support layers 330. The capacitor dielectric films 320 may be disposed on the etch stop films 200 and may contact the etch stop films 200. The capacitor dielectric films 320 may extend along the profile of the lower electrodes 310.

The capacitor dielectric films 320 may include a material such as silicon oxide, silicon nitride, silicon oxynitride, or a high dielectric constant material containing a metal. The capacitor dielectric films 320 are illustrated as being single films, but the present disclosure is not limited thereto.

In some embodiments, the capacitor dielectric films 320 may include a stacked film structure in which zirconium oxide, aluminum oxide, and zirconium oxide are sequentially stacked.

In some embodiments, the capacitor dielectric films 320 may include a dielectric film containing hafnium (Hf). In some embodiments, the capacitor dielectric films 320 may have a stacked film structure of ferroelectric and paraelectric material films.

The ferroelectric material film may have ferroelectric properties. The ferroelectric material film may have a thickness sufficient to exhibit ferroelectric properties. The thickness of the ferroelectric material film with ferroelectric properties may vary depending on the type of ferroelectric material.

For example, the ferroelectric material film may include a monometal oxide. The ferroelectric material film may include a monometal oxide film. Here, the monometal oxide may be a binary compound consisting of one metal and oxygen. A ferroelectric material film containing the monometal oxide may have an orthorhombic crystal structure.

For example, the metal included in the monometal oxide film may be Hf. The monometal oxide film may be a hafnium oxide (HfO) film. Here, the HfO film may have a stoichiometric chemical formula or a non-stoichiometric chemical formula.

In another example, the metal included in the monometal oxide film may be a rare earth metal belonging to the Lanthanoid series. The monometal oxide film may be a film of an oxide of a rare earth metal belonging to the Lanthanoid series. Here, the film of an oxide of a rare earth metal belonging to the Lanthanoid series may have a stoichiometric chemical formula or a non-stoichiometric chemical formula. When the ferroelectric material film includes the monometal oxide film, the ferroelectric material film may have a thickness of, for example, 1 nanometer (nm) to 10 nm.

For example, the ferroelectric material film may include a bimetal oxide. The ferroelectric material film may include a bimetal oxide film. Here, the bimetal oxide may be a ternary compound consisting of two metals and oxygen. A ferroelectric material film containing the bimetal oxide may have an orthorhombic crystal structure.

The metal included in the bimetal oxide film may be, for example, Hf and zirconium (Zr). The bimetal oxide film may be a hafnium zirconium oxide (HfₓZr₍₁₋ₓ₎O) film where x may be 0.2 or greater and 0.8 or less. Here, the HfₓZr₍₁₋ₓ₎O film may have a stoichiometric chemical formula or a non-stoichiometric chemical formula.

When the ferroelectric material film includes a bimetal oxide film, the ferroelectric material film may have a thickness of, for example, 1 nm to 20 nm.

For example, the paraelectric material film may be a dielectric film or a stacked film containing Zr, but the present disclosure is not limited thereto. Even with the same chemical formula, the dielectric material may exhibit ferroelectric or paraelectric properties depending on its crystal structure.

A paraelectric material may have a positive dielectric constant, whereas a ferroelectric material may have a negative dielectric constant within a certain range. That is, the paraelectric material may have a positive capacitance, while the ferroelectric material may have a negative capacitance.

Generally, when two or more capacitors with positive capacitance are connected in series, the total capacitance of the two capacitors decreases. However, when a capacitor with negative capacitance and a capacitor with positive capacitance are connected in series, the total capacitance of the two capacitors increases.

The upper electrode 340 may be disposed on the capacitor dielectric films 320. The upper electrode 340 may extend along the profile of the capacitor dielectric films 320. The upper electrode 340 may include a material such as a doped semiconductor material, a conductive metal nitride (e.g., titanium nitride, tantalum nitride, niobium nitride, or tungsten nitride), a metal (e.g., ruthenium, iridium, titanium, or tantalum), and a conductive metal oxide (e.g., iridium oxide or niobium oxide), but the present disclosure is not limited thereto. In some embodiments, the upper electrode 340 may include titanium nitride (TiN). Additionally, in some embodiments, the upper electrode 340 may include niobium nitride (NbN).

Referring to FIG. 4, the lower electrodes 310 may include first lower electrodes (e.g., first portions) 310_1, which are in contact with the landing pads 190, third lower electrodes 310_3 (e.g., third portions), which are on the first lower electrodes 310_1, and second lower electrodes 3102 (e.g., second portions), which are between the first lower electrodes 310_1 and the third lower electrodes 310_3.

In the first and second directions X and Y, a width W12 of the second lower electrodes 3102 may be smaller than a width W11 of the first lower electrodes 310_1 and a width W13 of the third lower electrodes 310_3. The first lower electrodes 310_1, the second lower electrodes 3102, and the third lower electrodes 310_3 may form an “I” shape together.

As will be described later, when the first lower electrodes 310_1 and the second lower electrodes 310_2 are formed integrally, the first lower electrodes 310_1 and the second lower electrodes 310_2 may include the same material.

The upper electrode 340 may include a first upper electrode 3401 (e.g., a first portion), which is on the etch stop films 200, and a second upper electrode 3402 (e.g., a second portion), which is on the first upper electrode 340_1. In the first and second directions X and Y, a width W23 of the second upper electrode 3402 may be smaller than a width W22 of the first upper electrode 340_1. Moreover, the width W23 of the second upper electrode 3402 may be smaller than each of the widths W11, W12, and W13 of the lower electrode 310.

In the first and second directions X and Y, the first lower electrodes 310_1 and the etch stop films 200 may be adjacent to (e.g., may overlap) one another, the second lower electrodes 310_2 and the first upper electrode 340_1 may be adjacent to (e.g., may overlap) each other, and the third lower electrodes 310_3 and the second upper electrode 340_2 may be adjacent to (e.g., may overlap) each other.

In this case, in the third direction Z, the first lower electrodes 310_1 and the etch stop films 200 may be disposed at the same first vertical level. For example, uppermost surfaces of the first lower electrodes 310_1 may be coplanar with uppermost surfaces of the etch stop films 200. The second lower electrodes 310_2 and the first upper electrode 340_1 may be disposed at the same second vertical level that is above the first vertical level. The third lower electrodes 310_3 and the second upper electrode 340_2 may also be disposed at the same third vertical level that is above the second vertical level.

In the first and second directions X and Y, the width W11 of the first lower electrodes 310_1 and a width W31 of the landing pads 190 may be the same. In this case, in the third direction Z, the side profile of the first lower electrodes 310_1 and the side profile of the landing pads 190 may be continuous. Sidewalls of the first lower electrodes 310_1 may thus be collinear with sidewalls of the landing pads 190 in the third direction Z.

The etch stop films 200 may have a substantially rectangular shape. In this case, in the third direction Z, the side profile of the etch stop films 200 and the side profile of the interlayer dielectric films 191 may be continuous. Accordingly, sidewalls of the etch stop films 200 may be collinear with sidewalls of the interlayer dielectric films 191 in the third direction Z.

For example, the landing pads 190, the first lower electrodes 310_1, and the second lower electrodes 310_2 may include the same material. In this case, the landing pads 190, the first lower electrodes 310_1, and the second lower electrodes 3102 may be formed as single/monolithic films. Alternatively, the landing pads 190, the first lower electrodes 310_1, and the second lower electrodes 3102 may include different materials. In this case, the landing pads 190, the first lower electrodes 310_1, and the second lower electrodes 310_2 may be formed as multilayer films containing different materials.

The landing pads 190, the first lower electrodes 310_1, and the second lower electrodes 3102 may include a material containing at least one selected from among Si, Ni, Ti, W, Mo, Zr, niobium (Nb), and Ta, a nitride of the material, and/or an oxide of the material.

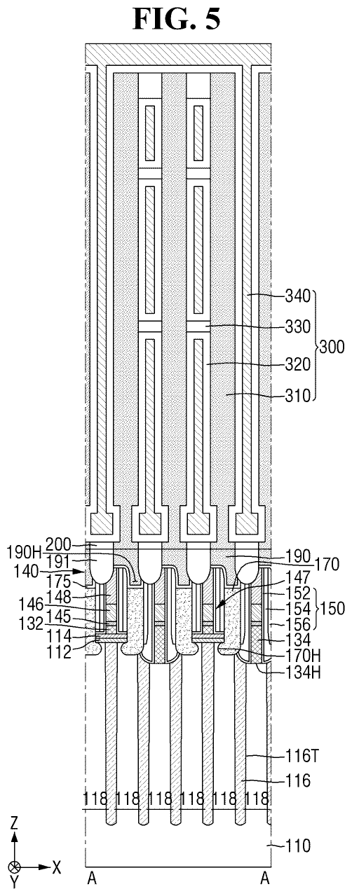

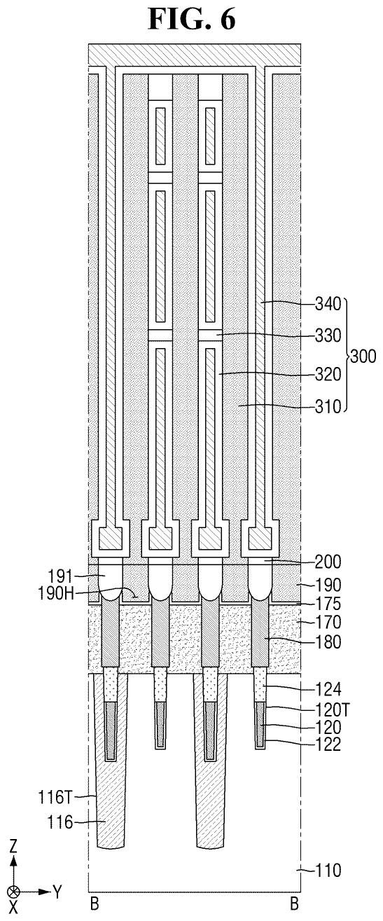

FIGS. 5 and 6 are cross-sectional views illustrating a semiconductor memory device according to some embodiments of the present disclosure. FIG. 5 corresponds to FIG. 2 (in that FIG. 5 is a cross-sectional view along the line A-A of FIG. 1), and FIG. 6 corresponds to FIG. 3 (in that FIG. 6 is a cross-sectional view along the line B-B of FIG. 1). For convenience, the embodiment of FIGS. 5 and 6 will hereinafter be described, focusing on differences from the embodiment of FIGS. 1 through 4.

Referring to FIGS. 5 and 6, the semiconductor memory device according to some embodiments of the present disclosure may further include a barrier film 175. The barrier film 175 may be disposed between bitline structures 140 and landing pads 190. The barrier film 175 may be disposed between buried contacts 170 and the landing pads 190. The barrier film 175 may cover at least portions of the top and side surfaces of the bitline structures 140 and the top surfaces of the buried contacts 170. The barrier film 175 may also cover the top surfaces of the buried contacts 170 and at least portions of the top and side surfaces of insulating fences 180.

The barrier film 175 may be formed on the buried contacts 170 before the formation of the landing pads 190. The barrier film 175 may include a conductive metal nitride such as tungsten nitride, titanium nitride, or tantalum nitride, but the present disclosure is not limited thereto.

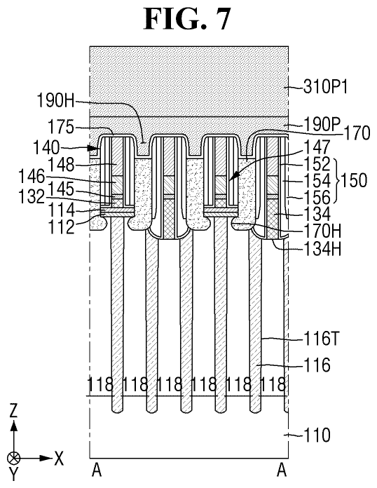

FIGS. 7 through 26 illustrate intermediate steps of a method of fabricating a semiconductor memory device according to some embodiments of the present disclosure. FIGS. 7 through 26 are cross-sectional views illustrating a method of fabricating the semiconductor memory device of FIGS. 5 and 6. For convenience, descriptions of content identical to that described above with reference to FIGS. 1 through 6 may be omitted.

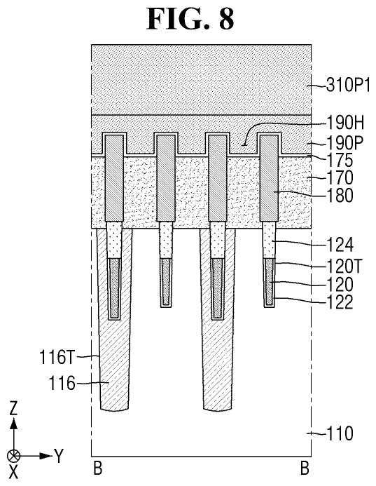

Referring to FIGS. 7 and 8, a barrier film 175 may be formed on at least portions of the top and side surfaces of bitline structures 140, the top surfaces of buried contacts 170, and at least portions of the top and side surfaces of insulating fences 180.

Thereafter, a pre-landing pad material layer 190P may be formed to fill landing pad holes 190H between the bitline structures 140. A first pre-lower electrode material layer 310P1 may be formed on the pre-landing pad material layer 190P.

The pre-landing pad material layer 190P and the first pre-lower electrode material layer 310P1 may include a material containing at least one selected from among Si, Ni, Ti, W, Mo, Zr, Nb, and Ta, a nitride of the material, and/or an oxide of the material.

In some embodiments, landing pads 190 may be formed using the pre-landing pad material layer 190P, and first lower electrodes 310_1 and second lower electrodes 310_2 may be formed using the first pre-lower electrode material layer 310P1. Accordingly, additional capacitance can be secured without excessively increasing the number of processes or the complexity of such processes.

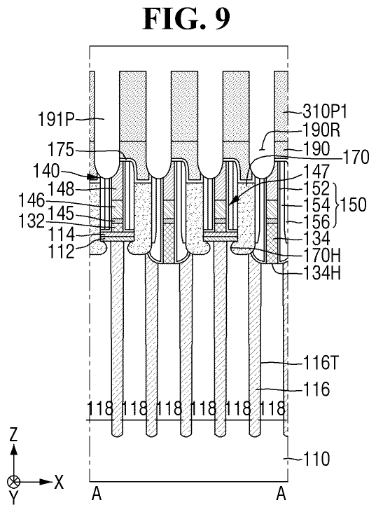

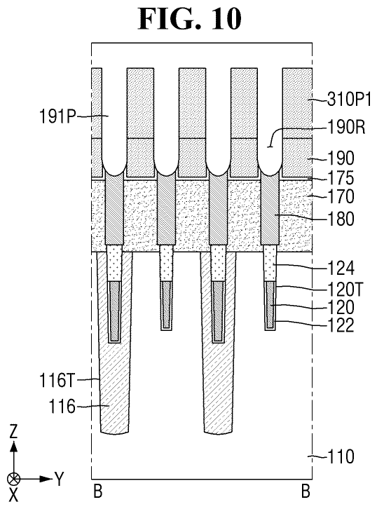

Referring to FIGS. 9 and 10, a plurality of landing pads 190, which fill at least portions of the landing pad holes 190H and extend onto the bitline structures 140, may be formed. Although not specifically illustrated, the formation of the landing pads 190 may involve forming a plurality of mask patterns on the first pre-lower electrode material layer 310P1 and etching the pre-landing pad material layer 190P and the first pre-lower electrode material layer 310P1 using the mask patterns. In this process, the bitline structures 140, the barrier film 175, and the insulating fences 180 may be at least partially etched, and as a result, landing pad recesses 190R may be formed between the landing pads 190.

Thereafter, a pre-interlayer dielectric material layer 191P may be formed to fill the landing pad recesses 190R. For example, the pre-interlayer dielectric material layer 191P may include silicon nitride.

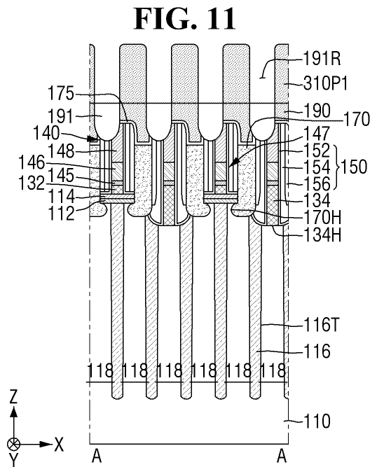

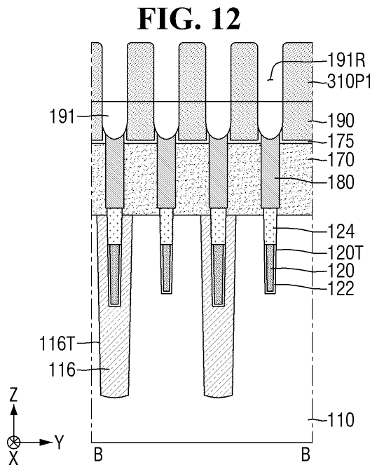

Referring to FIGS. 11 and 12, portions of the pre-interlayer dielectric material layer 191P on the sidewalls and top surface of the first pre-lower electrode material layer 310P1 may be removed to form interlayer dielectric recesses 191R. Accordingly, the interlayer dielectric recesses 191R may be alternately arranged with the landing pads 190.

The removal of the pre-interlayer dielectric material layer 191P may be performed by an etch-back process. In this process, although not specifically illustrated, upper corner portions of the first pre-lower electrode material layer 310P1 may also be etched to have a curved shape, but the present disclosure is not limited thereto.

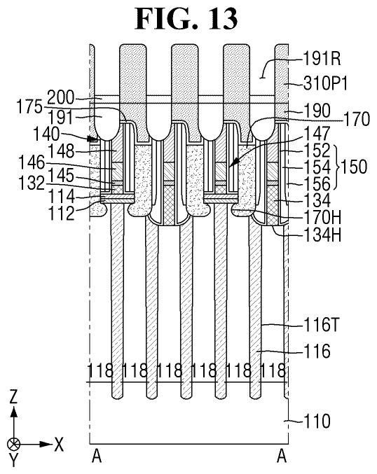

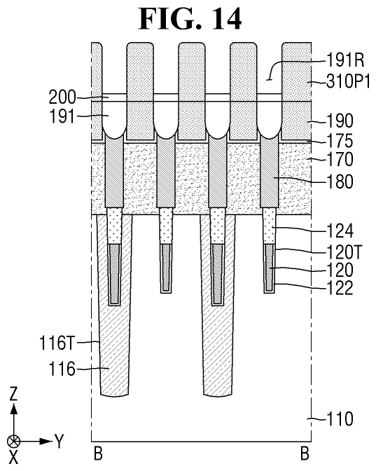

Referring to FIGS. 13 and 14, etch stop films 200 may be formed within the interlayer dielectric recesses 191R and on the top surfaces of interlayer dielectric films 191. For example, the etch stop films 200 may include silicon boron nitride.

Although not specifically illustrated, at least portions of the etch stop films 200 may be removed by an etch-back process.

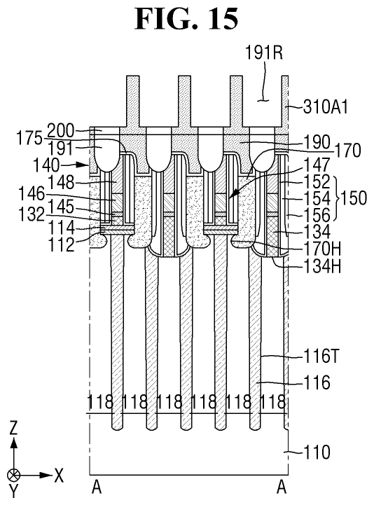

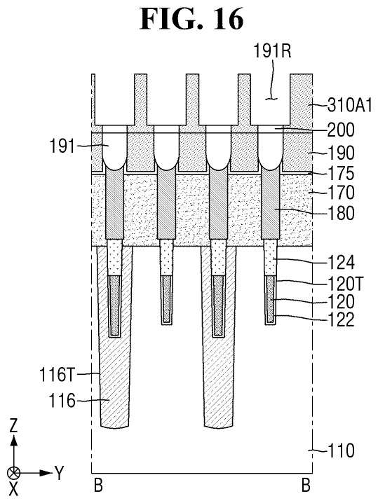

Referring to FIGS. 15 and 16, at least portions of the first pre-lower electrode material layer 310P1 may be etched by a wet etching process to form a first pre-lower electrode layer 310A1.

For example, as illustrated in FIGS. 15 and 16, the sidewalls of the first pre-lower electrode material layer 310P1 may be etched, and as a result, the widths, in the first and second directions X and Y, of the first pre-lower electrode layer 310A1 may be reduced compared to the widths, in the first and second directions X and Y, of the first pre-lower electrode material layer 310P1 of FIGS. 13 and 14.

As the sidewalls of the first pre-lower electrode material layer 310P1 are etched, the upper corner portions of the first pre-lower electrode layer 310A1 may have an angled shape, but the present disclosure is not limited thereto. Alternatively, the upper corner portions of the first pre-lower electrode layer 310A1 may also have a curved shape.

Consequently, the interior spaces of the interlayer dielectric recesses 191R may be expanded compared to that illustrated in FIGS. 13 and 14. Additionally, the widths, in the first and second directions X and Y, of the first pre-lower electrode layer 310A1 may differ between lower regions including the landing pads 190 and upper regions on the lower regions. That is, the width of the lower regions in contact with the landing pads 190 may be greater than the width of the upper regions.

The first pre-lower electrode layer 310A1 may be formed as first lower electrodes 310_1 and second lower electrodes 310_2, as illustrated in FIG. 4. Since the first pre-lower electrode layer 310A1 is formed integrally, no interfaces may exist between the first lower electrodes 310_1 and the second lower electrodes 310_2.

Contrary to what is illustrated in FIGS. 15 and 16, during the etching of the sidewalls of the first pre-lower electrode material layer 310P1, the profile of the sidewalls of the first pre-lower electrode layer 310A1 may not be parallel to the third direction Z.

In this case, the profile of the sidewalls of the second lower electrodes 310_2 of the lower electrode layer 310 may be inclined, and the widths, in the first and second directions X and Y, of the second lower electrodes 310_2 may decrease closer to (e.g., may be tapered toward) the third lower electrodes 310_3. Accordingly, by forming the width of lowermost portions of the third lower electrodes 310_3 to be greater than the width of uppermost portions of the second lower electrodes 3102, the lowermost portions of the third lower electrodes 310_3 may surround at least parts of the upper portions of the second lower electrodes 310_2. As a result, a greater contact area can be secured, improving connection reliability.

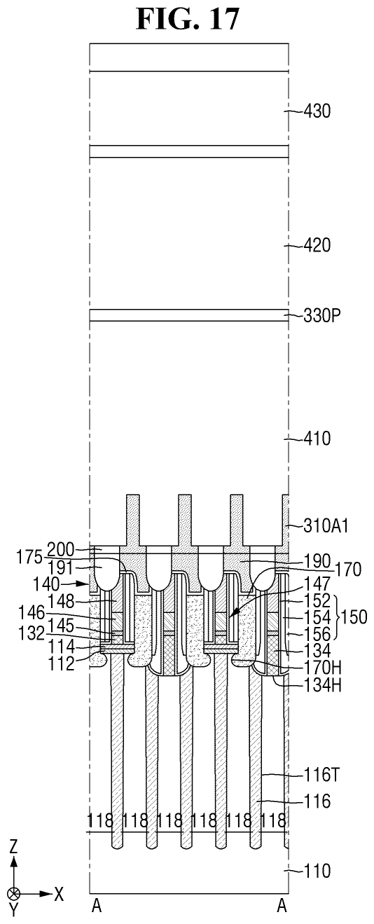

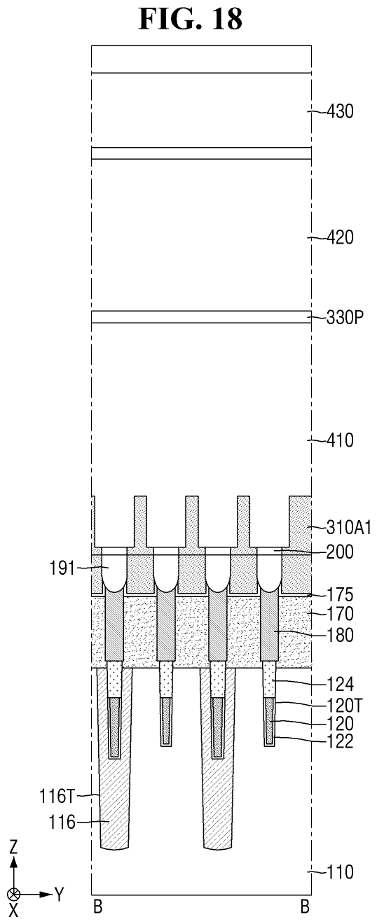

Referring to FIGS. 17 and 18, first, second, and third insulating layers 410, 420, and 430 may be sequentially formed on the etch stop films 200 and the first pre-lower electrode layer 310A1. For example, the first, second, and third insulating layers 410, 420, and 430 may include oxide. Pre-electrode support layers 330P may be formed between the first and second insulating layers 410 and 420, between the second and third insulating layers 420 and 430, and on the third insulating layer 430.

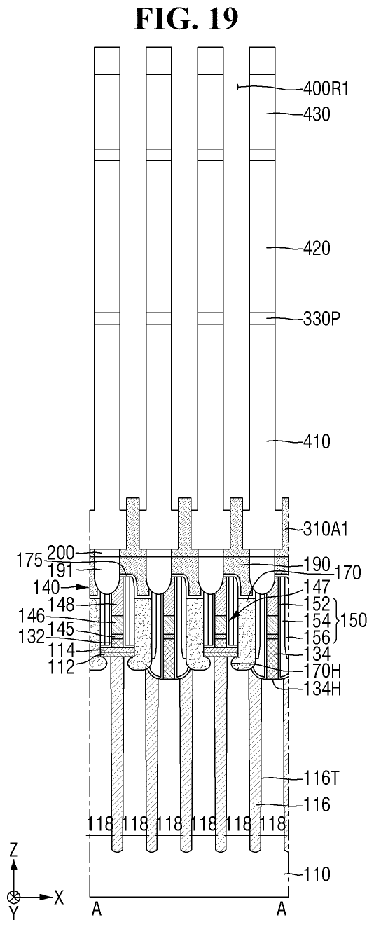

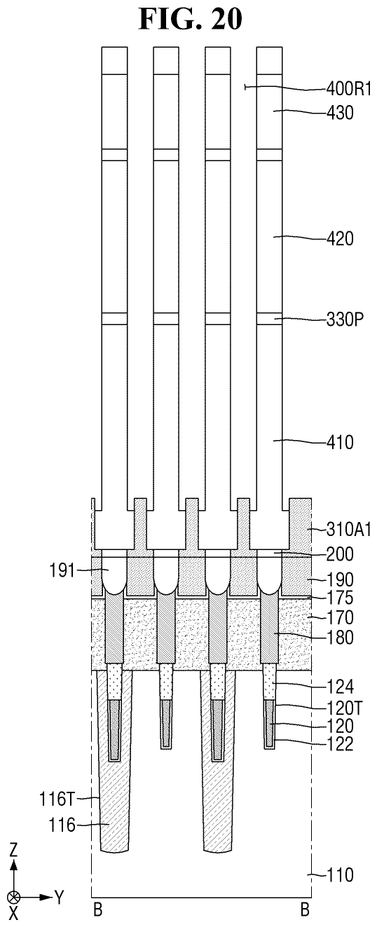

Referring to FIGS. 19 and 20, first recesses 400R1, which penetrate the first, second, and third insulating layers 410, 420, and 430 and the pre-electrode support layers 330P, may be formed. The first recesses 400R1 may expose portions of the top of the first pre-lower electrode layer 310A1.

Traditionally, after the etching of the first, second, and third insulating layers 410, 420, and 430, an additional process of removing the etch stop films 200 is required to connect the lower electrodes 310 and the landing pads 190. Conversely, in some embodiments, since the first pre-lower electrode layer 310A1 is exposed, additional capacitance can be secured without needing to remove the etch stop films 200 after the etching of the first, second, and third insulating layers 410, 420, and 430.

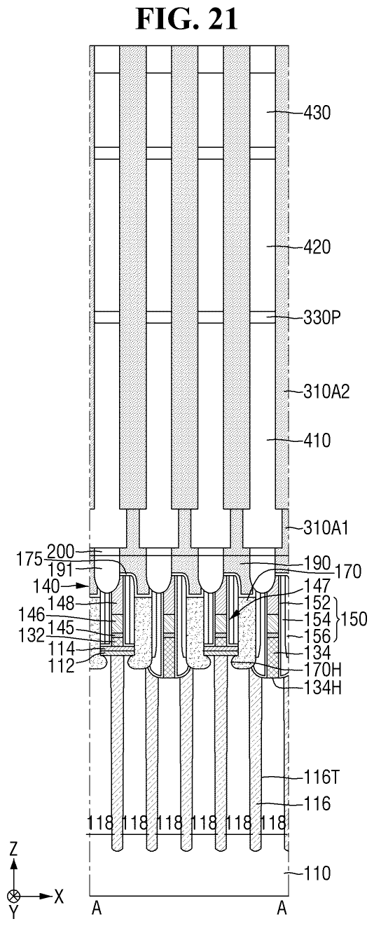

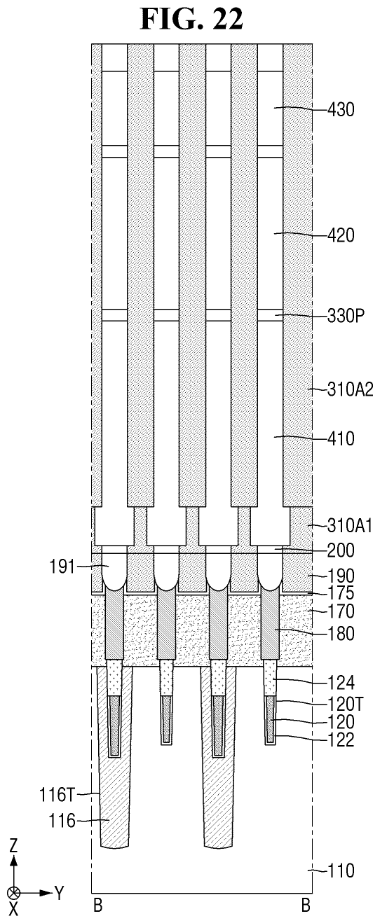

Referring to FIGS. 21 and 22, a second pre-lower electrode layer 310A2 may be formed within the first recesses 400R1 and on the first pre-lower electrode layer 310A1. The second pre-lower electrode layer 310A2 may be formed as the third lower electrodes 310_3 of FIG. 4.

As the second pre-lower electrode layer 310A2 is formed in a different process from the first pre-lower electrode layer 310A1, an interface may exist between the first and second pre-lower electrode layers 310A1 and 310A2, but the present disclosure is not limited thereto. Alternatively, there may be no substantial interface between the first and second pre-lower electrode layers 310A1 and 310A2 if the first and second pre-lower electrode layers 310A1 and 310A2 are formed of the same material.

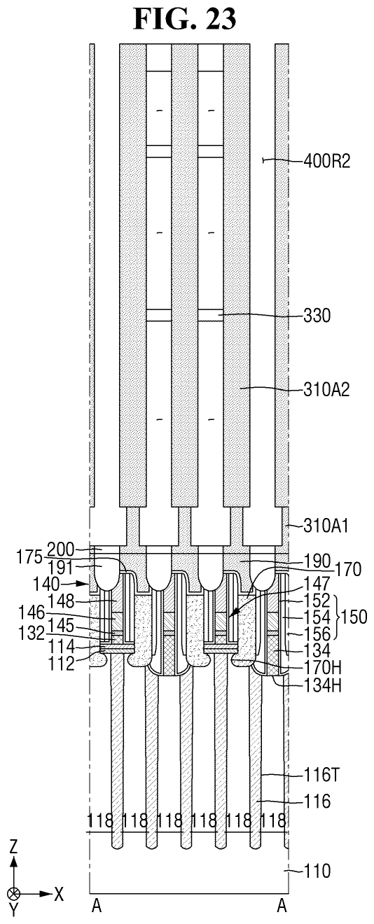

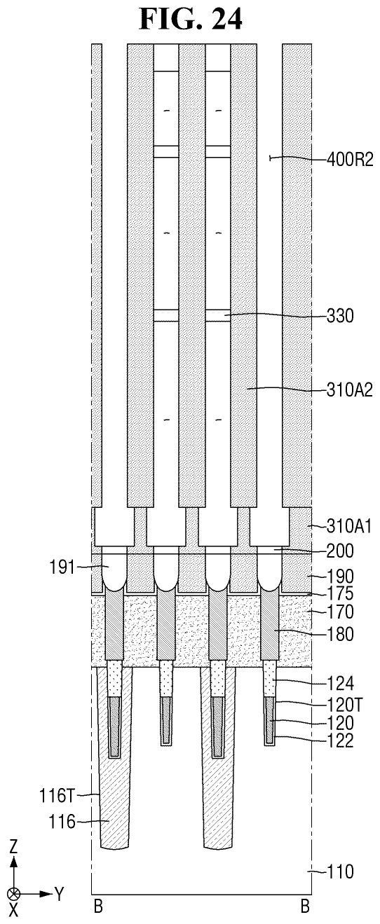

Referring to FIGS. 23 and 24, electrode support layers 330 and second recesses 400R2 may be formed by patterning the first, second, and third insulating layers 410, 420, and 430 and the pre-electrode support layers 330P.

The first, second, and third insulating layers 410, 420, and 430 may be removed through areas where the electrode support layers 330 are not formed.

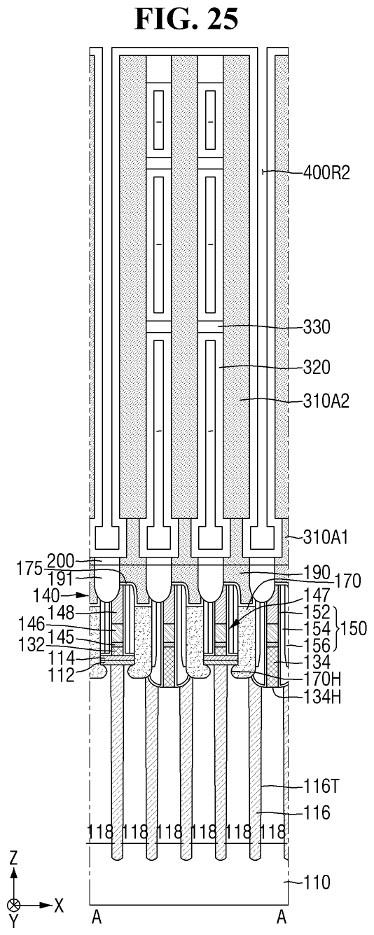

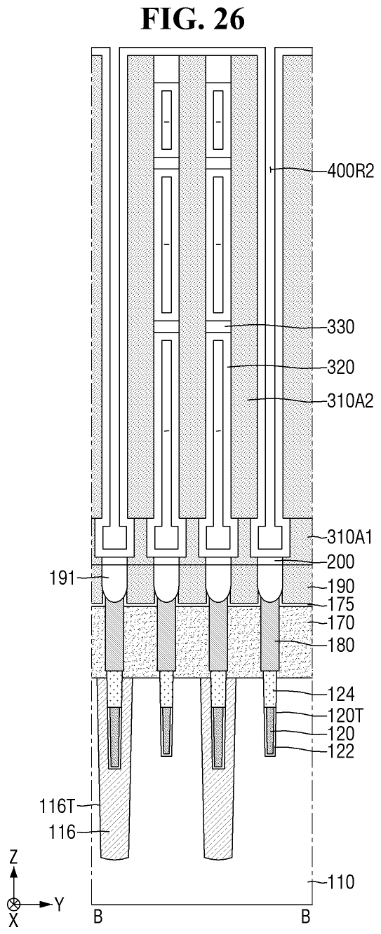

Referring to FIGS. 25 and 26, capacitor dielectric films 320 may be formed. The dielectric films 320 may be formed on the etch stop films 200, the landing pads 190, the first and second pre-lower electrode layers 310A1 and 310A2, and the electrode support layers 330.

Thereafter, referring again to FIGS. 5 and 6, an upper electrode 340 may be formed on the capacitor dielectric films 320. The upper electrode 340 may extend between lower electrodes 310 that are not connected by the electrode support layers 330. For example, the upper electrode 340 may include SiGe.

As a result, capacitor structures 300 may be formed.

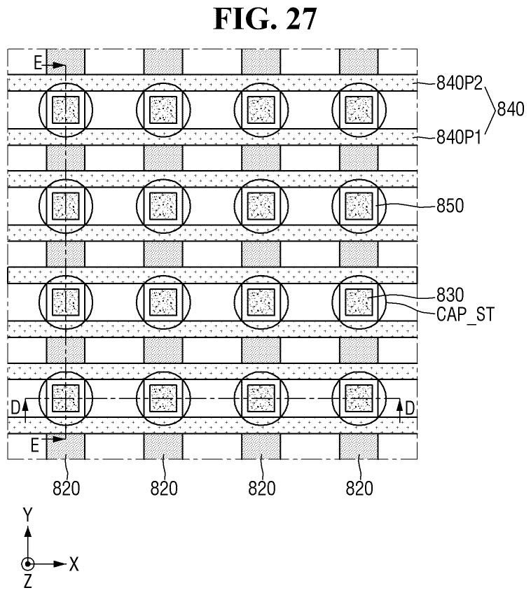

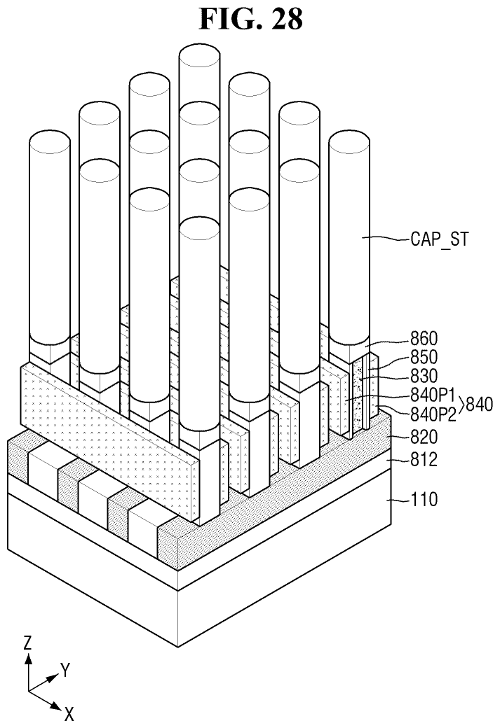

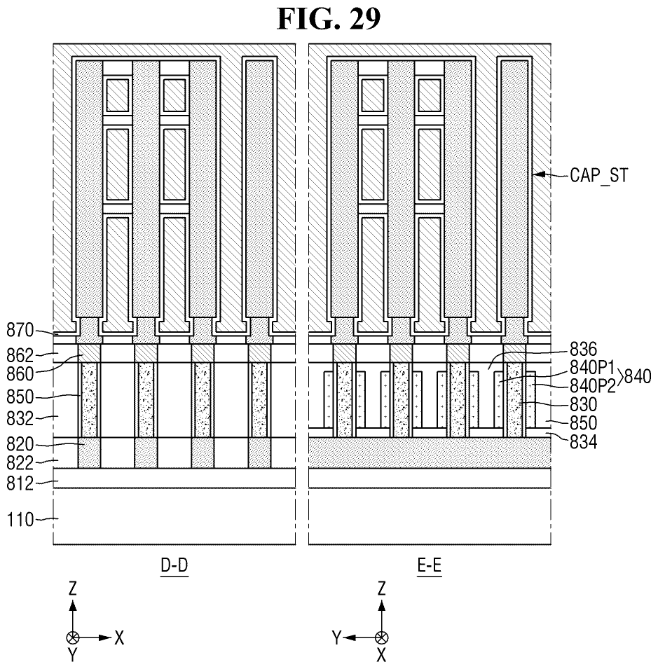

FIG. 27 is a layout view of a semiconductor memory device according to some embodiments of the present disclosure. FIG. 28 is a perspective view of the semiconductor memory device of FIG. 27. FIG. 29 is a cross-sectional view taken along lines D-D and E-E of FIG. 27. For convenience, the embodiment of FIGS. 27 through 29 will hereinafter be described, focusing on differences from the embodiment of FIGS. 1 through 6.

Referring to FIGS. 27 through 29, the semiconductor memory device according to some embodiments of the present disclosure may include a substrate 110, a plurality of first conductive lines 820, channel layers 830, gate electrodes 840, gate insulating films 850, and capacitors CAP_ST. The semiconductor memory device according to some embodiments of the present disclosure may be a memory device with vertical channel transistors (VCTs). The VCTs may comprise a structure where the channel length of the channel layers 830 extends along a vertical direction from the substrate 110.

A lower insulating layer 812 may be disposed on the substrate 110. The first conductive lines 820 may be spaced apart from one another in a first direction X and may extend in a second direction Y on the lower insulating layer 812. A plurality of first insulating patterns 822 may be disposed on the lower insulating layer 812 to fill the spaces between the first conductive lines 820. The first insulating patterns 822 may extend in the second direction Y. The top surfaces of the first insulating patterns 822 may be at the same level as the top surfaces of the first conductive lines 820. The first conductive lines 820 may function as bitlines.

The first conductive lines 820 may include a doped semiconductor material, a metal, a conductive metal nitride, a conductive metal silicide, a conductive metal oxide, or a combination thereof. For example, the first conductive lines 820 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but the present disclosure is not limited thereto. The first conductive lines 820 may include single or multiple layers of these materials. In some embodiments, the first conductive lines 820 may include graphene, carbon nanotube, or a combination thereof.

The channel layers 830 may be arranged in a matrix form on the first conductive lines 820 to be spaced apart from one another in the first and second directions X and Y. The channel layers 830 may have a first width in the first direction X and a first height in the third direction Z, and the first height may be greater than the first width. Here, the third direction Z may intersect the first and second directions X and Y and may be perpendicular to, for example, the top surface of the substrate 110. The first height may be, for example, about 2 to 10 times the first width, but the present disclosure is not limited thereto. Lower portions of the channel layers 830 may function as third source/drain regions (not illustrated in FIG. 27), upper portions of the channel layers 830 may function as fourth source/drain regions (not illustrated in FIG. 27), and portions of the channel layers 830 between the third source/drain regions and the fourth source/drain regions may function as channel regions (not illustrated in FIG. 27).

In some embodiments, the channel layers 830 may include an oxide semiconductor such as, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. The channel layers 830 may include a single layer or multiple layers of the oxide semiconductor. In some embodiments, the channel layers 830 may have a bandgap energy greater than that of Si. For example, the channel layers 830 may have a bandgap energy of about 1.5 eV to 5.6 eV. The channel layers 830 may have optimal channel performance when they have a bandgap energy of about 2.0 eV to 4.0 eV. The channel layers 830 may be polycrystalline or amorphous, but the present disclosure is not limited thereto. In some embodiments, the channel layers 830 may include graphene, carbon nanotube, or a combination thereof.

The gate electrodes 840 may extend in the first direction X on both (i.e., opposite) sidewalls of the channel layers 830. The gate electrodes 840 may include first sub-gate electrodes 840P1, which face first sidewalls of the channel layers 830 and second sub-gate electrode 840P2, which face second sidewalls opposite the first sidewalls of the channel layers 830. As the channel layers 830 are disposed between the first sub-gate electrodes 840P1 and the second sub-gate electrodes 840P2, the semiconductor device according to some embodiments of the present disclosure may have a dual gate transistor structure. However, the present disclosure is not limited to this. Alternatively, the second sub-gate electrodes 840P2 may not be provided, and only the first sub-gate electrodes 840P1 may be formed, thereby implementing a single gate transistor structure. The description for the material of the gate electrodes 840 may also be applicable to the material of the gate electrodes 120.

The gate insulating films 850 may surround the sidewalls of the channel layers 830 and may be interposed between the channel layers 830 and the gate electrodes 840. For example, referring to FIG. 29, the entire sidewalls of the channel layers 830 may be surrounded by the gate insulating films 850, and portions of the sidewalls of the gate electrodes 840 may contact the gate insulating films 850. In some embodiments, the gate insulating films 850 may extend in the extension direction of the gate electrodes 840 (i.e., the first direction X), and only two sidewalls of each of the channel layers 830 that face the gate electrodes 840 may contact the gate insulating films 850. The gate insulating films 850 may be formed of silicon oxide, silicon oxynitride, a high-k dielectric material with a greater dielectric constant than silicon oxide, or a combination thereof.

A plurality of second insulating patterns 832 may extend in the second direction Y on the first insulating patterns 822. The channel layers 830 may be disposed between pairs of adjacent second insulating patterns 832. Furthermore, first fill layers 834 and second fill layers 836 may be disposed in the spaces between the channel layers 830. The first fill layers 834 may be disposed at the bottoms of the spaces between the channel layers 830. The second fill layers 836 may be formed on the first fill layers 834 to fill the remaining spaces between the channel layers 830. The top surfaces of the second fill layers 836 may be at the same level as the top surfaces of the channel layers 830 and may cover the top surfaces of the second gate electrodes 840. Alternatively, the second insulating patterns 832 may be formed as continuous material layers with the first insulating patterns 822, or the second fill layers 836 may be formed as continuous material layers with the first fill layers 834.

Capacitor contacts 860 may be disposed on the channel layers 830. The capacitor contacts 860 may be disposed to vertically overlap with the channel layers 830 and may be arranged in a matrix form to be spaced apart from one another in the first and second directions X and Y. The capacitor contacts 860 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof. Upper insulating layers 862 may surround the sidewalls of the capacitor contacts 860, on the second insulating patterns 832 and the second fill layers 836.

Cell etch stop films 870 may be disposed on the upper insulating layers 862. Capacitors CAP_ST may be disposed on the cell etch stop films 870. The cell etch stop films 870 may correspond to the etch stop films 200 of FIGS. 2 and 3.

The capacitors CAP_ST may include lower electrodes, capacitor dielectric films, an upper electrode, and an electrode support structure. The lower electrodes may be electrically connected to the top surfaces of the capacitor contacts 860 by penetrating the cell etch stop films 870. The lower electrodes may be formed in a pillar shape, extending in the third direction Z, but the present disclosure is not limited thereto. In some embodiments, the lower electrodes may be disposed to vertically overlap with the capacitor contacts 860 and may be arranged in a matrix form to be spaced apart from one another in the first and second directions X and Y. Alternatively, landing pads (not illustrated in FIG. 29) may be further disposed between the capacitor contacts 860 and the lower electrodes, and the lower electrodes may be arranged in a hexagonal pattern. The electrode support structure can connect and support the lower electrode.

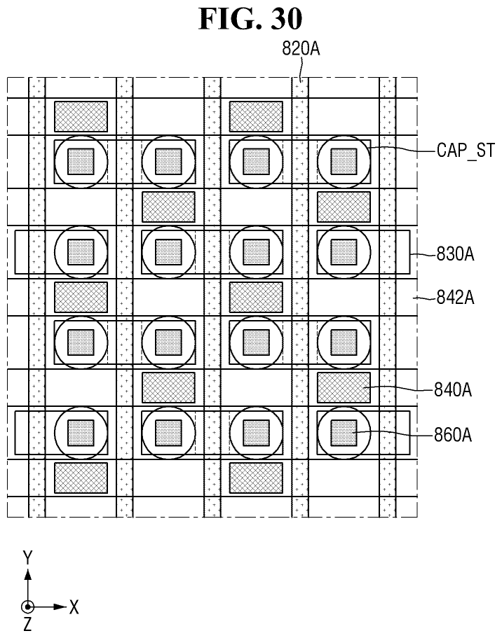

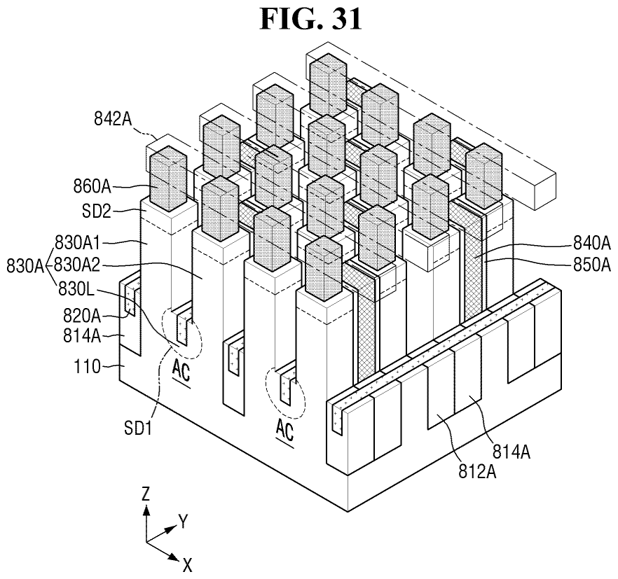

FIG. 30 is a layout view of a semiconductor memory device according to some embodiments of the present disclosure. FIG. 31 is a perspective view of the semiconductor memory device of FIG. 30. For convenience, the embodiment of FIGS. 30 and 31 will hereinafter be described, focusing on differences from the embodiment of FIGS. 27 through 29.

Referring to FIGS. 30 and 31, the semiconductor memory device according to some embodiments of the present disclosure may include a substrate 110, a plurality of first conductive lines 820A, channel structures 830A, contact gate electrodes 840A, a plurality of second conductive lines 842A, and capacitors CAP_ST. The semiconductor memory device according to some embodiments of the present disclosure may be a memory device with VCTs.

A plurality of active regions AC may be defined by first device isolation patterns 812A and second device isolation patterns 814A. The channel structures 830A may be disposed within the active regions AC. The channel structures 830A may include first active pillars 830A1 and second active pillars 830A2, which extend vertically, and connecting portions 830L, which are connected to lower portions of the first active pillars 830A1 and lower portions of the second active pillars 830A2. First source/drain regions SD1 may be disposed within the connecting portions 830L. Second source/drain regions SD2 may be disposed on the first active pillars 830A1 and the second active pillars 830A2. The first active pillars 830A1 and the second active pillars 830A2 may form independent unit memory cells.

The first conductive lines 820A may extend in a direction intersecting the active regions AC, for example, in a second direction Y. One first conductive line 820A may be disposed on a connecting portion 830L between first and second active pillars 830A1 and 830A2 and may also be disposed on a first source/drain region SD1, and a neighboring first conductive line 820A may be disposed between two channel structures 830A. Each of the first conductive lines 820A may function as a common bitline for two unit memory cells consisting of first and second active pillars 830A1 and 830A2 on either side of the corresponding first conductive line 820A.

Contact gate electrodes 840A may be disposed between pairs of adjacent channel structures 830A in the second direction Y. For example, a contact gate electrode 840A may be disposed between, and shared by, the first active pillar 830A1 of one channel structure 830A and the second active pillar 830A2 of a neighboring channel structure 830A, on its sidewalls. Gate insulating films 850A may be disposed between the contact gate electrodes 840A and the first active pillars 830A1, as well as between the contact gate electrodes 840A and the second active pillars 830A2. The second conductive lines 842A may extend in the first direction X on the top surfaces of the contact gate electrodes 840A. The second conductive lines 842A may function as wordlines of the semiconductor device according to some embodiments of the present disclosure.

Capacitor contacts 860A may be disposed on the channel structures 830A. The capacitor contacts 860A may be disposed on the second source/drain regions SD2, and capacitors CAP_ST may be disposed on the capacitor contacts 860A.

Embodiments of the present disclosure have been described above with reference to the accompanying drawings, but the present disclosure is not limited thereto and may be implemented in various different forms. It will be understood that embodiments of the present disclosure can be implemented in other specific forms without changing the scope of the present disclosure. Therefore, it should be understood that the embodiments set forth herein are illustrative in all respects and not limiting.

What is claimed is:

1. A semiconductor memory device comprising:
a substrate including active regions;
bitline structures extending in a direction on the active regions;
landing pads electrically connected to the active regions, on the bitline structures;
interlayer insulating films between the landing pads, on the bitline structures;
capacitor structures including lower electrodes that are on the landing pads, dielectric films that extend along the lower electrodes, and an upper electrode that is on the dielectric films; and
etch stop films between the interlayer insulating films and the capacitor structures,
wherein the upper electrode includes a first portion that is on the etch stop films, and a second portion that is on the first portion, and
wherein a width of the second portion is less than a width of the first portion.

2. The semiconductor memory device of claim 1, wherein the lower electrodes include first lower electrodes that contact the landing pads, third lower electrodes that are on the first lower electrodes, and second lower electrodes that are between the first lower electrodes and the third lower electrodes.

3. The semiconductor memory device of claim 2,
wherein a width of the second lower electrodes is less than a width of the first lower electrodes and less than a width of the third lower electrodes, and
wherein the width of the second portion of the upper electrode is less than the width of the second lower electrodes.

4. The semiconductor memory device of claim 2, wherein the first lower electrodes and the etch stop films overlap one another in the direction, the second lower electrodes and the first portion of the upper electrode overlap one another in the direction, and the third lower electrodes and the second portion of the upper electrode overlap one another in the direction.

5. The semiconductor memory device of claim 2, wherein a width of the first lower electrodes is equal to a width of the landing pads.

6. The semiconductor memory device of claim 2, wherein sidewalls of the first lower electrodes are collinear with sidewalls of the landing pads.

7. The semiconductor memory device of claim 2, wherein a width of the second lower electrodes is tapered toward the third lower electrodes.

8. The semiconductor memory device of claim 1, further comprising:
a barrier film between the bitline structures and the landing pads.

9. The semiconductor memory device of claim 1, wherein the capacitor structures further include a plurality of electrode support layers that support the lower electrodes.

10. The semiconductor memory device of claim 1, wherein the landing pads and the lower electrodes include a material comprising at least one of silicon (Si), nickel (Ni), titanium (Ti), tungsten (W), molybdenum (Mo), zirconium (Zr), niobium (Nb), or tantalum (Ta), or a nitride of the material, or an oxide of the material, or the nitride of the material and the oxide of the material.

11. The semiconductor memory device of claim 1, wherein the etch stop films include silicon boron nitride (SiBN).

12. A semiconductor memory device comprising:
a substrate including active regions that are defined by device isolation films;
wordline structures extending in a first direction on the active regions;
bitline structures extending in a second direction that intersects the first direction, on the wordline structures;
buried contacts electrically connected to the active regions, between the bitline structures;
landing pads electrically connected to the active regions, on the bitline structures;
interlayer insulating films between the landing pads, on the bitline structures;
capacitor structures including lower electrodes that are on the landing pads, dielectric films that extend along the lower electrodes, and an upper electrode that is on the dielectric films; and
etch stop films between the interlayer insulating films and the capacitor structures,
wherein the lower electrodes include first lower electrodes that contact the landing pads, third lower electrodes that are on the first lower electrodes, and second lower electrodes that are between the first lower electrodes and the third lower electrodes, and
wherein the first lower electrodes, the second lower electrodes, and the third lower electrodes form an “I” shape together.

13. The semiconductor memory device of claim 12, wherein a width of the second lower electrodes is less than a width of the first lower electrodes and a width of the third lower electrodes.

14. The semiconductor memory device of claim 12,
wherein the upper electrode includes a first portion that is on the etch stop films, and a second portion that is on the first portion, and
wherein a width of the second portion is less than a width of the first portion.

15. The semiconductor memory device of claim 12, further comprising:
a barrier film between the buried contacts and the landing pads.

16. The semiconductor memory device of claim 12, wherein in a third direction that is perpendicular to the first and second directions, sidewalls of the first lower electrodes are collinear with sidewalls of the landing pads.

17. The semiconductor memory device of claim 12, wherein in a third direction that is perpendicular to the first and second directions, sidewalls of the etch stop films are collinear with sidewalls of the interlayer insulating films.

18. The semiconductor memory device of claim 12, wherein the first lower electrodes and the second lower electrodes include the same material.

19. A semiconductor memory device comprising:
a substrate including active regions that are defined by device isolation films;
wordline structures extending in a first direction on the active regions;
bitline structures extending in a second direction that intersects the first direction, on the wordline structures;
buried contacts electrically connected to the active regions, between the bitline structures;
landing pads electrically connected to the active regions, on the bitline structures;
interlayer insulating films between the landing pads, on the bitline structures;
lower electrode structures including first lower electrodes that contact the landing pads, third lower electrodes that are on the first lower electrodes, and second lower electrodes that are between the first lower electrodes and the third lower electrodes;
etch stop films on the interlayer insulating films; and
an upper electrode structure including a first portion that is on the etch stop films, and a second portion that is on the first portion,
wherein a width of the second lower electrodes is less than a width of the first lower electrodes, and
wherein a width of the second portion of the upper electrode structure is less than a width of the first portion of the upper electrode structure.

20. The semiconductor memory device of claim 19, wherein in a third direction perpendicular to the first and second directions, the first lower electrodes and the etch stop films are at the same level, the second lower electrodes and the first portion of the upper electrode structure are at the same level, and the third lower electrodes and the second portion of the upper electrode structure are at the same level.
